(19) United States
(12) Patent Application Publication
(10) Pub. No.: US 2025/0379162 A1
(43) Pub. Date: Dec. 11, 2025

(54) HYBRID DTC EMBEDDING SUBSTRATE

(71) Applicant: QUALCOMM Incorporated, San Diego, CA (US)

(72) Inventors: Seongryul CHOI, Seongnam (KR); Kuiwon KANG, San Diego, CA (US); Hong Bok WE, San Diego, CA (US); Jung Won PARK, Gumi (KR)

(21) Appl. No.: 18/734,352

(22) Filed: Jun. 5, 2024

(51) Int. Cl. H01L 23/64; H01L 21/48; H01L 23/498; H05K 1/03; H05K 1/11; H05K 1/18; H05K 3/40

(52) U.S. Cl. CPC H01L 23/642; H01L 21/4857; H01L 23/49833; H01L 23/49894; H05K 1/0366; H05K 1/115; H05K 1/183; H05K 3/4038; H05K 2201/09545; H05K 2201/10015; H05K 2203/02; H05K 2203/0703

(57) ABSTRACT

Disclosed are semiconductor modules with hybrid deep trench capacitor (DTC) substrate. The semiconductor modules are hybrid in that they include both ajinomoto build-up film (ABF) and PrePreG (PPG). The ABF avoids or at least mitigates resin void risks. The PPG avoids or at least mitigates delamination and via crack risks.

### BACKGROUND OF THE DISCLOSURE

### 1. Field of the Disclosure

This disclosure relates generally to semiconductor devices or modules, and more specifically, but not exclusively, to semiconductor device/modules that include hybrid deep trench capacitor (DTC) embedding substrate.

### 2. Description of the Related Art

Integrated circuit (IC) technology has achieved great strides in advancing computing power through miniaturization of active components. In current semiconductor devices and modules, deep trench capacitor (DTC) can be provided in a thick core substrate. However, depending on the materials used, issues can arise. Such issues include high resin void risk (e.g., due to less resin content for thick core), high delamination risk (e.g., due to reduced adhesion). Accordingly, there is a need for systems, apparatus, and methods that overcome the deficiencies of conventional semiconductor modules including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary semiconductor module is disclosed. The semiconductor module may comprise a core. The semiconductor module may also comprise a deep trench capacitor (DTC) within a DTC cavity of the core. The semiconductor module may further comprise ajinomoto build-up film (ABF) filling spaces between the DTC and the core on the one or both sides of the DTC. The semiconductor module may yet comprise one or more upper metal layers on an upper surface of the DTC and on an upper surface of the core. The semiconductor module may yet further comprise one or more lower metal layers on a lower surface of the core. The semiconductor module may in addition comprise an upper prepreg (PPG) on an upper surface of the DTC and on an upper surface the core. The upper PPG may encapsulate sides of the one or more upper metal layers.

A method of fabricating an exemplary semiconductor module is disclosed. The method may comprise providing a core. The method may also comprise forming a deep trench capacitor (DTC) within a DTC cavity of the core. The method may further comprise filling spaces between the DTC and the core on the one or both sides of the DTC with ajinomoto build-up film (ABF). The method may yet comprise forming one or more upper metal layers on an upper surface of the DTC and on an upper surface of the core. The method may yet further comprise forming one or more lower metal layers on a lower surface of the core. The method may in addition comprise forming an upper prepreg (PPG) on an upper surface of the DTC and on an upper surface the core. The upper PPG may encapsulate sides of the one or more upper metal layers.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1A illustrates a view of a conventional semiconductor module that suffers from resin void.

FIG. 1B illustrates a portion of the conventional semiconductor module of FIG. 1A where resin void is present.

FIG. 2A illustrates a view of a conventional semiconductor module that suffers from delamination and/or via crack.

FIG. 2B illustrates a portion of the conventional semiconductor module of FIG. 2A where delamination and/or via crack are present.

FIGS. 3A, 3B and 3C illustrate semiconductor modules in accordance with one or more aspects of the disclosure.

FIGS. 4A-4J illustrate examples of stages of fabricating a semiconductor module in accordance with one or more aspects of the disclosure.

FIGS. 5-7 illustrate flow charts of example methods of manufacturing a semiconductor module in accordance with at one or more aspects of the disclosure.

FIG. 8 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are semiconductor modules and methods for fabricating the same. In an aspect, the semiconductor module may comprise a core on one or both sides of a deep trench capacitor (DTC). The semiconductor module may also comprise ajinomoto build-up film (ABF) filling spaces between the DTC and the core on the one or both sides of the DTC. The semiconductor module may further comprise one or more upper metal layers on an upper surface of the DTC and on an upper surface of the core. The semiconductor module may yet comprise one or more lower metal layers on a lower surface of the core. The semiconductor module may yet further comprise an upper prepreg (PPG) on an upper surface of the DTC and on an upper surface the core. The upper PPG may encapsulate sides of the one or more upper metal layers.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

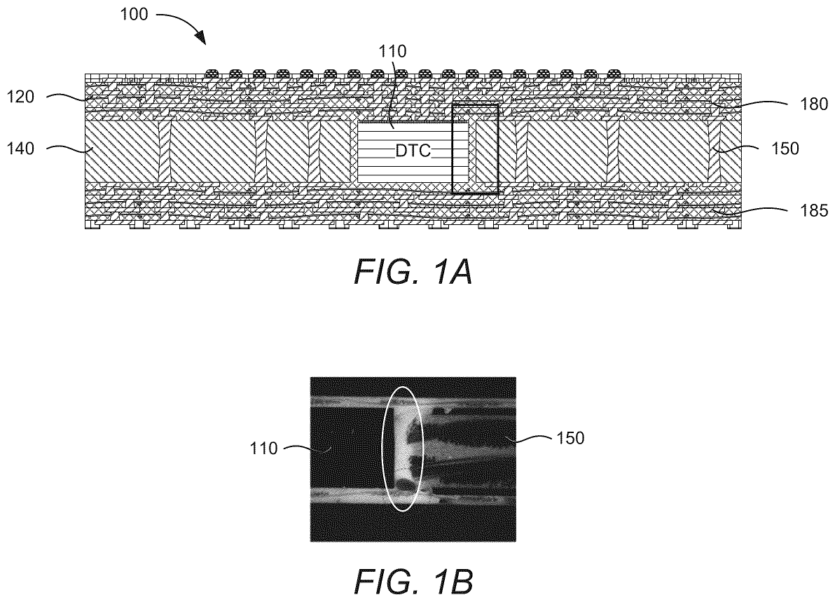

As indicated above, conventional semiconductor modules suffer from high resin void risk and/or high delamination risk among others. FIG. 1A illustrates a view of a conventional semiconductor module 100, which includes a core 140 on both sides of a deep trench capacitor DTC 110. The semiconductor module 100 also includes upper metal layers 180 and lower metal layers 185 respectively formed on upper and lower surfaces of the core 140 and of the DTC 110. A thru-core via 150 formed of copper electrically connects the upper and lower metal layers 180, 185. An upper prepreg (PPG) 120 is formed on upper surface of the DTC 110 and on upper surface the core 340.

The PPG 120 is formed under high temperature, high pressure process, which presses the PPG material vertically. Unfortunately, due to small resin content of such process, there is a high risk of forming resin voids. This is illustrated in FIG. 1B that shows a blow-up region of FIG. 1A (highlighted in rectangle). As seen in FIG. 1B, space between the core 140 and the DTC 110, there is little to no resin, i.e., the ellipse highlights a region of resin void. This can present issues such as reducing structural integrity.

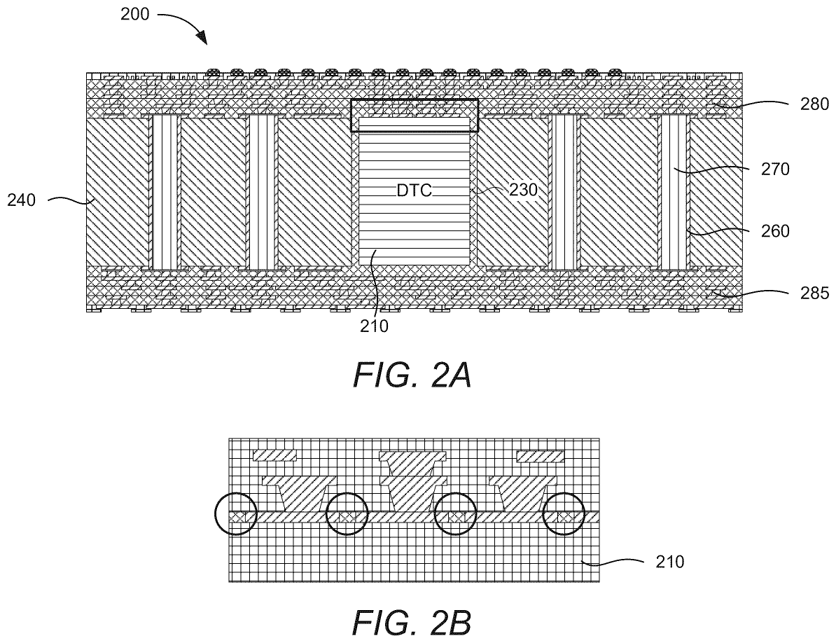

FIG. 2A illustrates a view of another conventional semiconductor module 200, which in many respects, is similar to the conventional semiconductor module 100 of FIG. 2A. The conventional semiconductor module 200 includes a core 240 on both sides of a deep trench capacitor DTC 210. The semiconductor module 200 also includes upper metal layers 280 and lower metal layers 285 respectively formed on upper and lower surfaces of the core 140 and of the DTC 110. The spaces between the DTC 210 and the core 340 are filled with ajinomoto build-up film (ABF) 230.

Unlike the semiconductor module 100, the semiconductor module 200 does not include a solid thru-core via. Instead, the semiconductor module 200 includes thru-core connects 260 formed on sides surfaces of thru-core cavities to electrically connect upper and lower metal layers 280, 285. The remainder of the thru-core cavities are plugged with the ABF material.

The semiconductor 200 suffers from high delamination and/or via crack risks. This is illustrated in FIG. 2A that shows up a blow-up region of FIG. 2B (highlighted in rectangle). As seen, delamination and/or cracks can develop as highlighted with circles. The delamination and/or cracks develops due to less adhesion between the ABF and pads of the DTC 210.

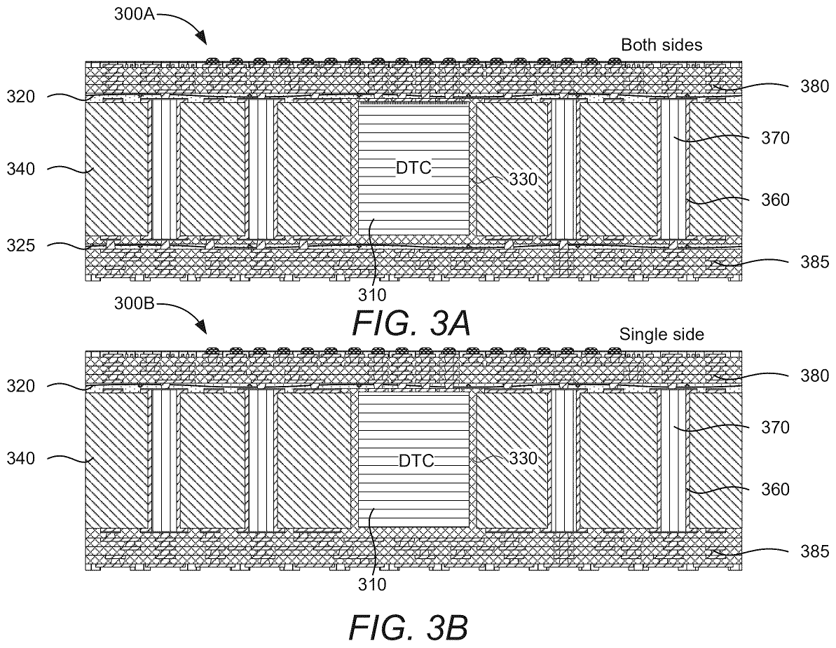

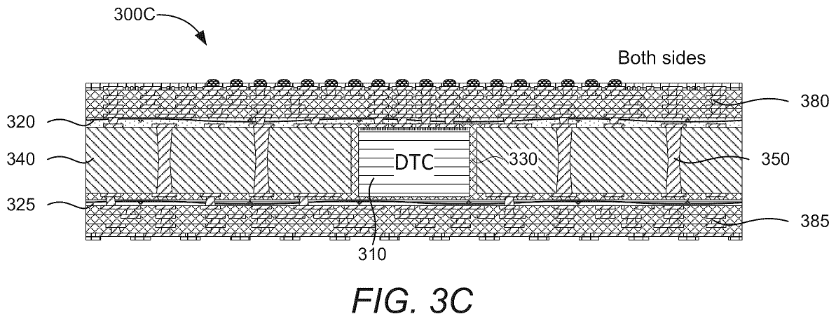

To address these and other issues of the conventional semiconductor modules, it is proposed to provide hybrid semiconductor module that avoids and/or mitigates, among others, the issues of resin voids and delamination and/or via cracks. This is illustrated in FIGS. 3A-3C. FIG. 3A illustrates a semiconductor module 300A in accordance with one or more aspects of the disclosure. The semiconductor module 300A may include a deep trench capacitor (DTC) 310 and a core 340 on one or both sides of the DTC 310.

The semiconductor module 300A may also include ajinomoto build-up film (ABF) 330 filling spaces between the DTC 310 and the core 340 on the one or both sides of the DTC 310. In this way, the resin void issue can be mitigated or even avoided altogether.

The semiconductor module 300A may include one or more upper metal layers 380 on upper surface of the DTC 310 and on upper surface of the core 340. In an aspect, the one or more upper metal layers 380 may serve as upper redistribution layers (RDL). In another aspect, terminals for the DTC 310 may be on the upper surface of the DTC 310. Then the terminals of the DTC 310 may be electrically coupled to the one or more upper metal layers 380. For example, the terminals may be in direct contact with at least some of the one or more upper metal layers 380.

An upper prepreg (PPG) 320 may be formed on an upper surface of the DTC 310 and on an upper surface the core 340. The upper PPG 320 may be formed through a modified semi-additive process (mSAP) under high temperature and/or high pressure. As such, adherence between the upper PPG 320 and the upper surfaces of the DTC 310 can be high. This can mitigate or even avoid delamination and/or via cracks from being formed. The upper PPG 320 may include a woven glass material. In an aspect, the upper PPG 320 may encapsulate sides of the one or more upper metal layers 380.

The semiconductor module 300A may include one or more lower metal layers 385 on lower surface of the core 340. In an aspect, the one or more lower metal layers 385 may serve as lower RDLs.

A lower PPG 325 may be formed on a lower surface of the DTC 310 and/or on a lower surface the core 340. The lower PPG 325 may also be formed through a modified semi-additive process (mSAP) under high temperature and/or high pressure. Thus, delamination and/or via cracks on the lower surfaces of the DTC 310 and/or the core 340 can be mitigated or even avoided. In an aspect, the lower PPG 325 include woven glass material, and may encapsulate sides of the one or more lower metal layers 385.

One or more thru-core connects 360 may be formed in one or more thru-core cavities (discussed further below) within the core 340. In particular, the one or more thru-core connects 360 may be plated on side surfaces of the one or more thru-core cavities from the upper surface to the lower surface of the core 340. The one or more thru-core connects 360 may electrically couple the one or more upper metal layers 380 with the one or more lower metal layers 385. For example, the one or more thru-core connects 360 may be in direct contact with the one or more upper metal layers 380 and/or with the one or more lower metal layers 385. The one or more thru-core connects 360 may be formed from conductive metals such as copper (Cu).

One or more thru-core plugs 370 may fill the remainder of the one or more thru-core cavities from the upper surface to the lower surface of the core 340. The one or more thru-core plugs 370 may provide structural support. As a result, relatively thick cores and/or DTCs may be supported. For example, thicknesses of the core 340 and/or the DTC 310 may be 400 μm or more. In one aspect, the one or more thru-core plugs 370 may be formed from the ABF material. Alternatively, the one or more thru-core plugs 370 may be formed from materials different from the ABF material.

Note that the semiconductor module 300A includes PPGs 320 and 325, i.e., it can include PPG on both upper and lower surfaces of the core 340 and/or the DTC 310. However, this is not strictly a requirement. FIG. 3B illustrates a semiconductor 300B in which PPG is included on one side. The semiconductor module 300B may be similar to the semiconductor module 300A in almost all respects. However, as seen, semiconductor module 300B only includes one PPG. In this instance, the semiconductor module 300B may include the upper PPG 320, but not the lower PPG 325. More broadly, PPG may be included on the surface of the DTC 310 that includes the terminals of the DTC 310. Again, the semiconductor module 300B may be used for relatively thick cores (e.g., 400 μm or more).

FIG. 3C illustrates a semiconductor module 300C in accordance with one or more aspects of the disclosure. The semiconductor module 300C may be similar to the semiconductor module 300A in many respects. For example, the semiconductor module 300C may include core 340 on one or both sides of DTC 310, ABF 330 filling spaces between the DTC 310 and the core 340 on the one or both sides of the DTC 310, one or more upper metal layers 380 on upper surface of the DTC 310 and on an upper surface of the core 340, one or more lower metal layers 385 on lower surface of the core 340, upper PPG 320 on upper surface of the DTC 310 and on upper surface the core 340, lower PPG 325 on lower surface of the DTC 310 and on lower surface the core 340, and so on.

The semiconductor module 300C may differ from the semiconductor module 300A in how the upper and lower metal layers 380, 385 are electrically coupled with each other. instead of the thru-core connects, one or more thru-core vias 350 may be formed within the core 340 from the upper surface to the lower surface of the core 340. The one or more thru-core vias 350 may electrically couple the one or more upper metal layers 380 with the one or more lower metal layers 385. For example, the one or more thru-core vias 350 may in contact with the one or more upper metal layers 380 and with the one or more lower metal layers 385. The one or more thru-core vias 350 may be formed from conductive metal such as copper.

Note that the one or more thru-core vias 350 may be solid. That is, the thru-core plugs are not necessary. The semiconductor module 300C may have cores and/or DTC that are relatively thin. For example, thickness of the core 340 and/or the DTC 310 may be 400 μm or less.

The semiconductor module 300C is another example in which the PPGs can be on both sides of the core 340 and/or the DTC 310. While not shown, a PPG on a single side is also contemplated. That is, a version of the semiconductor module 300C may include the upper PPG 320 and not the lower PPG 325. More broadly, PPG may be included on the surface of the DTC 310 that includes the terminals of the DTC 310.

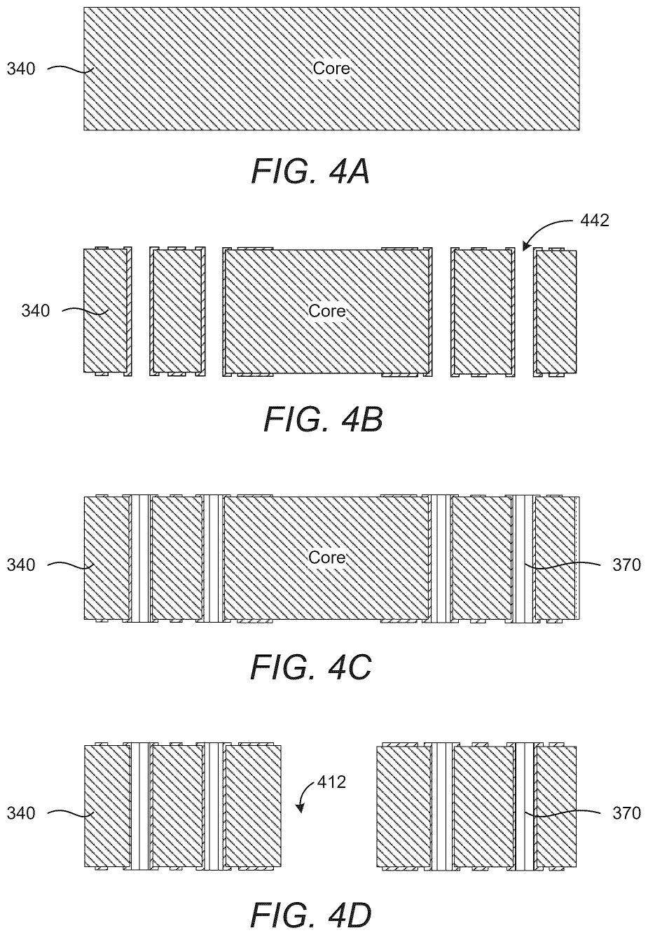

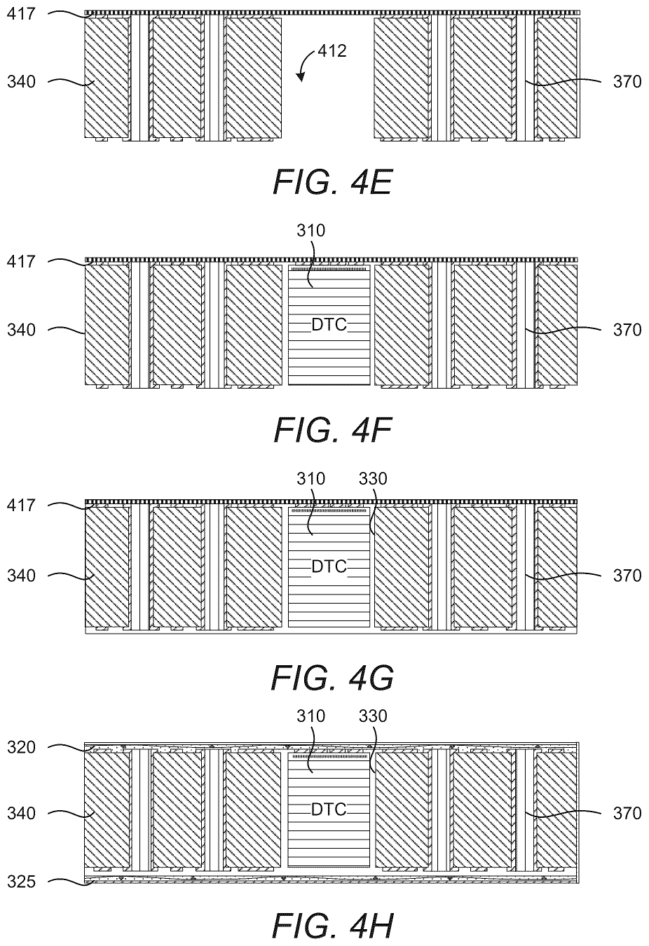

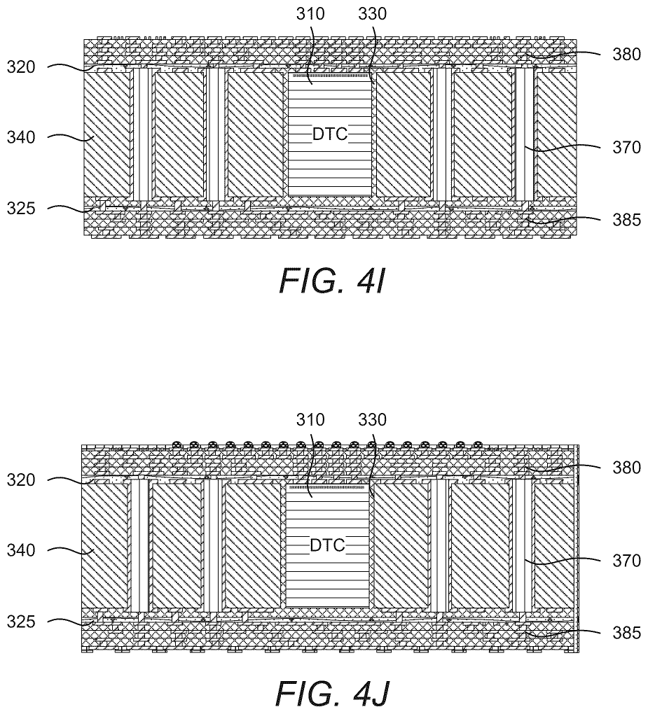

FIGS. 4A-4J illustrate examples of stages of fabricating a semiconductor module—such as the semiconductor modules 300A, 300B, 300C—in accordance with at one or more aspects of the disclosure.

FIG. 4A illustrates a stage in which core 340 is provided.

FIG. 4B illustrates a stage in which the core 340 is drilled to form one or more thru-core cavities 442.

FIG. 4C illustrates a stage in which sides of the one or more thru-core cavities 442 are plated with metal to form one or more thru-core connects 360. Also, the remainder of the one or more thru-core cavities 442 may be plugged, e.g., with plugging ink, which may be same or different from the ABF material. Further, the upper surface of the core 340 may be plated with at least one upper metal layer 380 of the one or more upper metal layers 380, e.g., to form electrical pads.

FIG. 4D illustrates a stage in which a DTC cavity 412 is formed within the core 340.

FIG. 4E illustrates a stage in which a PL tape lamination is applied on the upper surface of the core 340.

FIG. 4F illustrates a stage in which the DTC 310 is formed within the DTC cavity 412.

FIG. 4G illustrates a stage in which the spaces between the DTC 310 and the core 340 on the one or both sides of the DTC 310 is filled with the ABF 330.

FIG. 4H illustrates a stage in which the PL tape lamination is removed. Also, the upper PPG 320 may be formed on upper surface the DTC 310 and/or on upper surface the core 340. Further, the lower PPG 325 may be formed on lower surface the DTC 310 and/or on lower surface the core 340.

FIG. 4I illustrates a stage in which the one or more upper metal layers 380 may be formed on upper surfaces of the core 340 and/or the DTC 310. Also, the one or more lower metal layers 385 may be formed on lower surfaces of the core 340 and/or the DTC 310.

FIG. 4J illustrates a stage in which solder resist (SR) may be formed and surface finishing may be performed.

The semiconductor module 300A may be fabricated with the process illustrated in stages of FIGS. 4A-4J. However, if only a single PPG is desired (e.g., semiconductor module 300B), then the process may be altered as follows. The stage illustrated in FIG. 4H may be altered to only include the upper PPG 320 after the tape removal.

In FIGS. 4A-4J, the thru-core plug 370 may be formed of material different from ABF material. However, if it is desired that the thru-core plug 370 be formed from the ABF material, then the process may be altered as follows. In the stage illustrated in FIG. 4C, the one or more thru-core cavities 442 need NOT be filled. Rather in the stage illustrated in FIG. 4G, the ABF material may fill the one or more thru-core cavities 442 with the ABF materials as well as the spaces between the core 340 and the DTC 310.

In another alternative, if it is desired to incorporate the thru-core vias 350, then the process may be altered as follows. In the stage illustrated in FIG. 4C, the one or more thru-core cavities 442 may be filled with conductive material (e.g., copper) to form the thru-core vias 350. There would be no need to form the thru-core plugs 370.

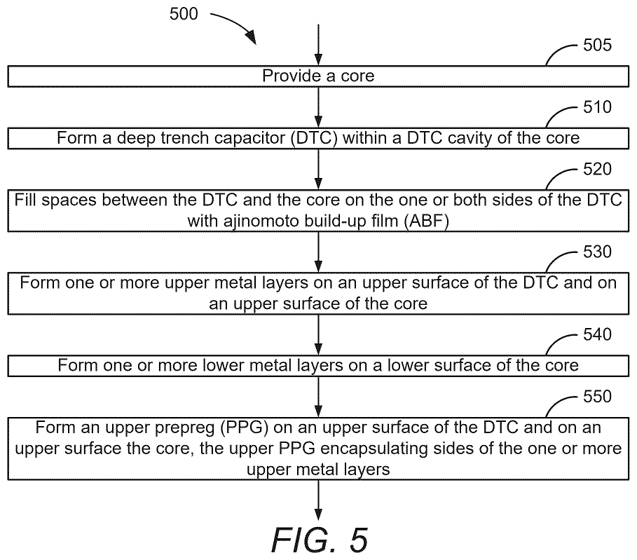

FIG. 5 illustrates a flow chart of an example method 500 of fabricating a semiconductor module, such as the semiconductor modules 300A, 300B, 300C, in accordance with at one or more aspects of the disclosure.

In block 505, a core 340 may be provided.

In block 510, a deep trench capacitor (DTC) 310 may be formed within a DTC cavity of the core.

In block 520, spaces between the DTC 310 and the core 340 on the one or both sides of

the DTC 310 may be filled with ABF 330.

In block 530, one or more upper metal layers 380 may be formed on an upper surface of the DTC 310 and on an upper surface of the core 340.

In block 540, one or more lower metal layers 385 may be formed on a lower surface of the core 340.

In block 550, an upper PPG 320 may be formed on an upper surface of the DTC 310 and on an upper surface the core 340. The upper PPG 320 may encapsulate sides of the one or more upper metal layers 380.

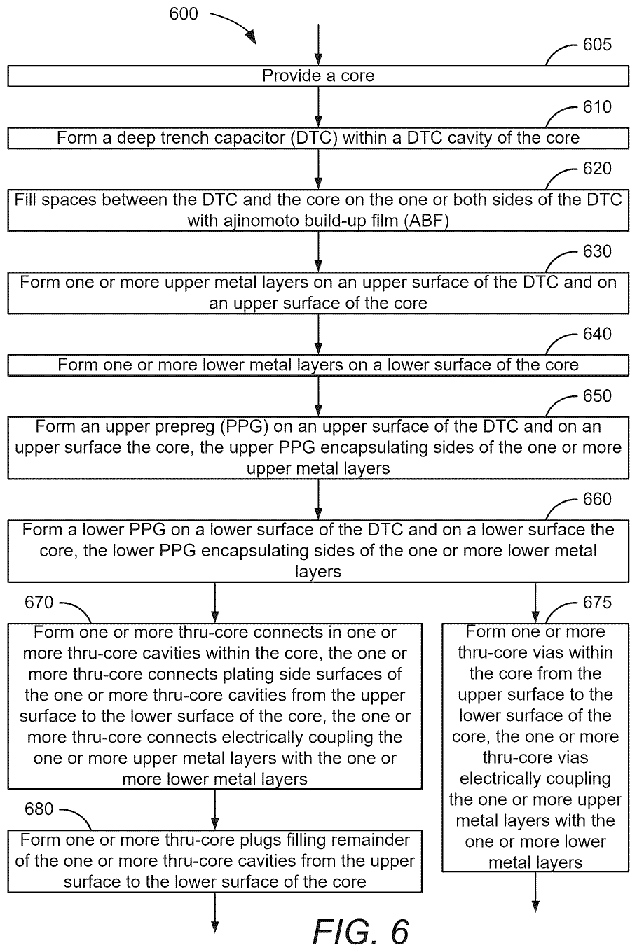

FIG. 6 illustrates a flow chart of an example method 600 of fabricating a semiconductor module, such as the semiconductor module 300 in accordance with at one or more aspects of the disclosure. FIG. 6 may be viewed as being more comprehensive than FIG. 5.

Block 605 may be similar to block 505. That is, in block 605, a core 340 may be provided.

Block 610 may be similar to block 510. That is, in block 610, a deep trench capacitor (DTC) 310 may be formed within a DTC cavity of the core.

Block 620 may be similar to block 520. That is, in block 620, spaces between the DTC 310 and the core 340 on the one or both sides of the DTC 310 may be filled with ABF 330.

Block 630 may be similar to block 530. That is, in block 630, one or more upper metal layers 380 may be formed on an upper surface of the DTC 310 and on an upper surface of the core 340.

Block 640 may be similar to block 540. That is, in block 640, one or more lower metal layers 385 may be formed on a lower surface of the core 340.

In block 650, may be similar to block 550. That is, in block 650, an upper PPG 320 may be formed on an upper surface of the DTC 310 and on an upper surface the core 340. The upper PPG 320 may encapsulate sides of the one or more upper metal layers 380.

In block 660, a lower PPG 325 may be formed on a lower surface of the DTC 310 and on

a lower surface the core 340. The lower PPG 325 may encapsulate sides of the one or more lower metal layers 385. It should be noted that block 660 may be optional in that if a single sided PPG is desired, block 660 can be skipped.

From here, the method may proceed to two directions—one for thicker cores (e.g., 400 μm or more) or for thinner cores (e.g., 400 μm or less). For the thicker core, in block 670, one or more thru-core connects 360 may be formed in the one or more thru-core cavities 442 within the core 340. The one or more thru-core connects 360 may be plated on side surfaces of the one or more thru-core cavities 442 from the upper surface to the lower surface of the core 340. As mentioned, the one or more thru-core connects 360 may electrically couple the one or more upper metal layers 380 with the one or more lower metal layers 385.

In block 680, one or more thru-core plugs 370 may fill a remainder of the one or more thru-core cavities 442 from the upper surface to the lower surface of the core 340.

For the thinner core, in block 675, one or more thru-core vias 350 may be formed within the core 340 from the upper surface to the lower surface of the core 340. The one or more thru-core vias 350 may electrically couple the one or more upper metal layers 380 with the one or more lower metal layers.

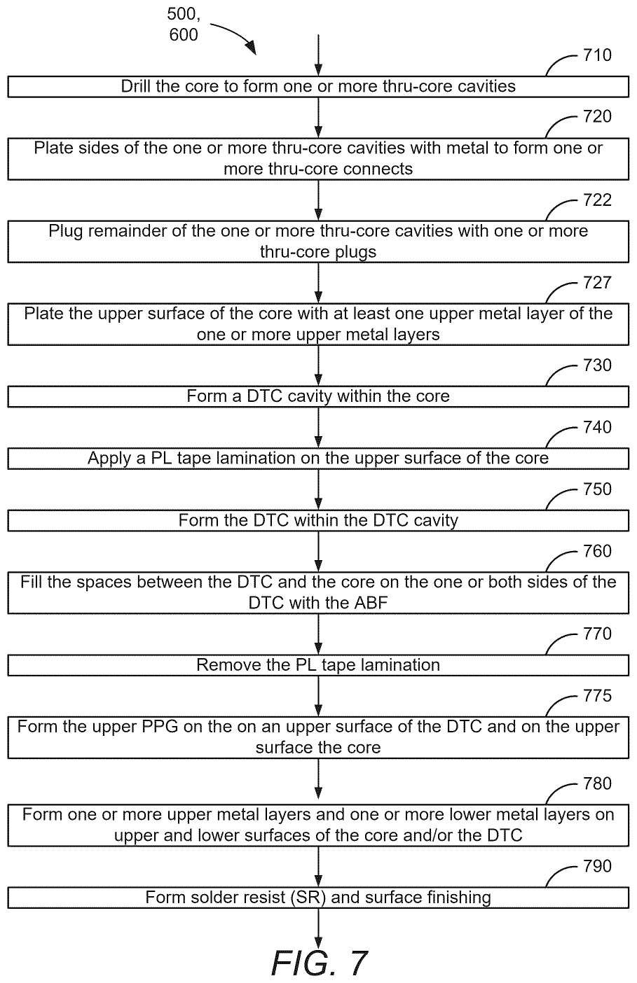

FIG. 7 illustrates a flow chart of an example process to perform the method 500, 600 of fabricating a semiconductor module in accordance with at one or more aspects of the disclosure.

In block 710, the core 340 may be drilled to form one or more thru-core cavities (442). Block 710 may correspond to the stages illustrated in FIGS. 4A and 4B.

In block 720, sides of the one or more thru-core cavities 442 may be plated with metal (e.g., copper) to form one or more thru-core connects 360.

In block 722, remainder of the one or more thru-core cavities 442 may be plugged with one or more thru-core plugs 370.

In block 727, the upper surface of the core 340 may be plated or otherwise patterned with at least one upper metal layer 380 of the one or more upper metal layers 380. Blocks 720, 722 and 727 may correspond to the stage illustrated in FIG. 4C.

In block 730, a DTC cavity 412 may be formed within the core 340. Block 730 may correspond to the stage illustrated in FIG. 4D.

In block 740, a PL tape lamination may be applied on the upper surface of the core (340). Block 740 may correspond to the stage illustrated in FIG. 4E.

In block 750, the DTC 310 may be formed within the DTC cavity 412. Block 750 may correspond to the stage illustrated in FIG. 4F.

In block 760, the spaces between the DTC 310 and the core 340 on the one or both sides of the DTC 310 may be filled with the ABF 330. Block 760 may correspond to the stage illustrated in FIG. 4G.

In block 770, the PL tape lamination may be removed.

In block 775, the upper PPG 320 may be formed on the on an upper surface of the DTC 310 and on the upper surface the core 340. The lower PPG 325 may also be formed on the on a lower surface of the DTC 310 and on the lower surface the core 340. Blocks 770 and 775 may correspond to the stage illustrated in FIG. 4H.

In block 780, one or more upper metal layers 380 may be formed the upper surfaces of the core 340 and the DTC 310. In addition, one or more lower metal layers 385 may be formed the lower surfaces of the core 340 and the DTC 310. Block 780 may correspond to the stage illustrated in FIG. 4I.

In block 790, solder resist (SR) may be formed. Also, surface finishing may be performed. Block 790 may correspond to the stage illustrated in FIG. 4J.

The following should be noted regarding the flow indicated in FIGS. 5-7. Unless otherwise indicated, the flow of blocks do not necessarily limit the ordering in which the blocks may be performed. In other words, the blocks may be performed in any order that is logical.

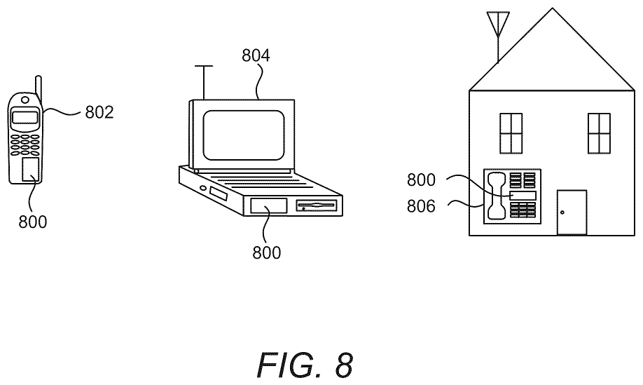

FIG. 8 illustrates various electronic devices 800 that may be integrated with any of the aforementioned semiconductor module in accordance with various aspects of the disclosure. For example, a mobile phone device 802, a laptop computer device 804, and a fixed location terminal device 806 may each be considered generally user equipment (UE) and may include one or more semiconductor modules (e.g., semiconductor module 300A, 300B, 300C) as described herein. The devices 802, 804, 806 illustrated in FIG. 8 are merely exemplary. Other electronic devices may also include the die modules including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IOT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and moduled into an antenna on glass device. The antenna on glass device may then be employed in devices described herein.

Implementation examples are described in the following numbered clauses:

Clause 1: A semiconductor module, comprising: a core; a deep trench capacitor (DTC) within a DTC cavity of the core; ajinomoto build-up film (ABF) filling spaces between the DTC and the core on the one or both sides of the DTC; one or more upper metal layers on an upper surface of the DTC and on an upper surface of the core; one or more lower metal layers on a lower surface of the core; and an upper prepreg (PPG) on an upper surface of the DTC and on an upper surface the core, the upper PPG encapsulating sides of the one or more upper metal layers.

Clause 2: The semiconductor module of clause 1, wherein terminals for the DTC are on the upper surface of the DTC.

Clause 3: The semiconductor module of any of clauses 1-2, further comprising: a lower PPG on a lower surface of the DTC and on the lower surface the core, the lower PPG encapsulating sides of the one or more lower metal layers.

Clause 4: The semiconductor module of clauses 1-3, further comprising: one or more thru-core connects in one or more thru-core cavities within the core, the one or more thru-core connects plating side surfaces of the one or more thru-core cavities from the upper surface to the lower surface of the core, the one or more thru-core connects electrically coupling the one or more upper metal layers with the one or more lower metal layers; and one or more thru-core plugs filling remainder of the one or more thru-core cavities from the upper surface to the lower surface of the core.

Clause 5: The semiconductor module of clause 4, wherein the one or more thru-core connects are formed from metal.

Clause 6: The semiconductor module of any of clauses 4-5, wherein a thickness of the core is 400 μm or more.

Clause 7: The semiconductor module of any of clauses 4-6, wherein the one or more thru-core plugs are formed from materials different from the ABF material.

Clause 8: The semiconductor module of any of clauses 4-7, wherein the one or more thru-core plugs are formed from the ABF material.

Clause 9: The semiconductor module of any of clauses 1-3, further comprising: one or more thru-core vias within the core from the upper surface to the lower surface of the core, the one or more thru-core vias electrically coupling the one or more upper metal layers with the one or more lower metal layers.

Clause 10: The semiconductor module of clause 9, wherein the one or more thru-core vias are formed from metal.

Clause 11: The semiconductor module of any of clauses 9-10, wherein a thickness of the core is 400 μm or less.

Clause 12: The semiconductor module of any of clauses 1-11, wherein the semiconductor module is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Clause 13: A method of fabricating a semiconductor module, the method comprising: providing a core; forming a deep trench capacitor (DTC) within a DTC cavity of the core; filling spaces between the DTC and the core on the one or both sides of the DTC with ajinomoto build-up film (ABF); forming one or more upper metal layers on an upper surface of the DTC and on an upper surface of the core; forming one or more lower metal layers on a lower surface of the core; and forming an upper prepreg (PPG) on an upper surface of the DTC and on an upper surface the core, the upper PPG encapsulating sides of the one or more upper metal layers.

Clause 14: The method of clause 13, wherein terminals for the DTC are on the upper surface of the DTC.

Clause 15: The method any of clauses 13-14, further comprising: forming a lower PPG on a lower surface of the DTC and on the lower surface the core, the lower PPG encapsulating sides of the one or more lower metal layers.

Clause 16: The method of any of clauses 13-15, further comprising: forming one or more thru-core connects in one or more thru-core cavities within the core, the one or more thru-core connects plating side surfaces of the one or more thru-core cavities from the upper surface to the lower surface of the core, the one or more thru-core connects electrically coupling the one or more upper metal layers with the one or more lower metal layers; and forming one or more thru-core plugs filling remainder of the one or more thru-core cavities from the upper surface to the lower surface of the core.

Clause 17: The method of clause 16, wherein the one or more thru-core connects are formed from metal.

Clause 18: The method of any of clause 16-17, wherein a thickness of the core is 400 82 m or more.

Clause 19: The method of any of clause 16-18, wherein the one or more thru-core plugs are formed from materials different from the ABF material.

Clause 20: The method of clause 16-19, wherein the one or more thru-core plugs are formed from the ABF material.

Clause 21: The method of any of clauses 13-15, further comprising: forming one or more thru-core vias within the core from the upper surface to the lower surface of the core, the one or more thru-core vias electrically coupling the one or more upper metal layers with the one or more lower metal layers.

Clause 22: The method of clause 21, wherein the one or more thru-core vias are formed from metal.

Clause 23: The method of any of clauses 21-22, wherein a thickness of the core is 400 μm or less.

Clause 24: The method of any of clauses 14-23, wherein fabricating the semiconductor module comprises: drilling the core to form one or more thru-core cavities; plating sides of the one or more thru-core cavities with metal to form one or more thru-core connects; plugging remainder of the one or more thru-core cavities with one or more thru-core plugs; plating the upper surface of the core with at least one upper metal layer of the one or more upper metal layers; forming a DTC cavity within the core; applying a PL tape lamination on the upper surface of the core; forming the DTC within the DTC cavity; filling the spaces between the DTC and the core on the one or both sides of the DTC with the ABF; removing the PL tape lamination; and forming the upper PPG on the on an upper surface of the DTC and on the upper surface the core.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that—although a dependent claim can refer in the claims to a specific combination with one or one or more claims—other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A semiconductor module, comprising:
a core;
a deep trench capacitor (DTC) within a DTC cavity of the core;
ajinomoto build-up film (ABF) filling spaces between the DTC and the core on the one or both sides of the DTC;
one or more upper metal layers on an upper surface of the DTC and on an upper surface of the core;
one or more lower metal layers on a lower surface of the core; and
an upper prepreg (PPG) on an upper surface of the DTC and on an upper surface the core, the upper PPG encapsulating sides of the one or more upper metal layers.

2. The semiconductor module of claim 1, wherein terminals for the DTC are on the upper surface of the DTC.

3. The semiconductor module of claim 1, further comprising:
a lower PPG on a lower surface of the DTC and on the lower surface the core, the lower PPG encapsulating sides of the one or more lower metal layers.

4. The semiconductor module of claim 1, further comprising:
one or more thru-core connects in one or more thru-core cavities within the core, the one or more thru-core connects plating side surfaces of the one or more thru-core cavities from the upper surface to the lower surface of the core, the one or more thru-core connects electrically coupling the one or more upper metal layers with the one or more lower metal layers; and
one or more thru-core plugs filling remainder of the one or more thru-core cavities from the upper surface to the lower surface of the core.

5. The semiconductor module of claim 4, wherein the one or more thru-core connects are formed from metal.

6. The semiconductor module of claim 4, wherein a thickness of the core is 400 μm or more.

7. The semiconductor module of claim 4, wherein the one or more thru-core plugs are formed from materials different from the ABF material.

8. The semiconductor module of claim 4, wherein the one or more thru-core plugs are formed from the ABF material.

9. The semiconductor module of claim 1, further comprising:
one or more thru-core vias within the core from the upper surface to the lower surface of the core, the one or more thru-core vias electrically coupling the one or more upper metal layers with the one or more lower metal layers.

10. The semiconductor module of claim 9, wherein the one or more thru-core vias are formed from metal.

11. The semiconductor module of claim 9, wherein a thickness of the core is 400 μm or less.

12. The semiconductor module of claim 1, wherein the semiconductor module is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

13. A method of fabricating a semiconductor module, the method comprising:
providing a core;
forming a deep trench capacitor (DTC) within a DTC cavity of the core;
filling spaces between the DTC and the core on the one or both sides of the DTC with ajinomoto build-up film (ABF);
forming one or more upper metal layers on an upper surface of the DTC and on an upper surface of the core;
forming one or more lower metal layers on a lower surface of the core; and
forming an upper prepreg (PPG) on an upper surface of the DTC and on an upper surface the core, the upper PPG encapsulating sides of the one or more upper metal layers.

14. The method of claim 13, wherein terminals for the DTC are on the upper surface of the DTC.

15. The method of claim 13, further comprising:
forming a lower PPG on a lower surface of the DTC and on the lower surface the core, the lower PPG encapsulating sides of the one or more lower metal layers.

16. The method of claim 13, further comprising:
forming one or more thru-core connects in one or more thru-core cavities within the core, the one or more thru-core connects plating side surfaces of the one or more thru-core cavities from the upper surface to the lower surface of the core, the one or more thru-core connects electrically coupling the one or more upper metal layers with the one or more lower metal layers; and
forming one or more thru-core plugs filling remainder of the one or more thru-core cavities from the upper surface to the lower surface of the core.

17. The method of claim 16, wherein the one or more thru-core connects are formed from metal.

18. The method of claim 13, further comprising:
forming one or more thru-core vias within the core from the upper surface to the lower surface of the core, the one or more thru-core vias electrically coupling the one or more upper metal layers with the one or more lower metal layers.

19. The method of claim 18, wherein the one or more thru-core vias are formed from metal.

20. The method of claim 13, wherein fabricating the semiconductor module comprises:
drilling the core to form one or more thru-core cavities;
plating sides of the one or more thru-core cavities with metal to form one or more thru-core connects;
plugging remainder of the one or more thru-core cavities with one or more thru-core plugs;
plating the upper surface of the core with at least one upper metal layer of the one or more upper metal layers;
forming a DTC cavity within the core;
applying a PL tape lamination on the upper surface of the core;
forming the DTC within the DTC cavity;
filling the spaces between the DTC and the core on the one or both sides of the DTC with the ABF;
removing the PL tape lamination; and
forming the upper PPG on an upper surface of the DTC and on the upper surface the core.
